(19) United States
(12) Patent Application Publication
(10) Pub. No.: US 2023/0375930 A1
(43) Pub. Date: Nov. 23, 2023

(54) PHOTOSENSITIVE RESIN MULTILAYER BODY

(71) Applicant: ASAHI KASEI KABUSHIKI KAISHA, Tokyo (JP)

(72) Inventors: Shinichi KUNIMATSU, Tokyo (JP); Junya KOSAKA, Tokyo (JP)

(73) Assignee: ASAHI KASEI KABUSHIKI KAISHA, Tokyo (JP)

(21) Appl. No.: 18/030,668

(22) PCT Filed: Sep. 24, 2021
(86) PCT No.: PCT/JP2021/035139

§ 371 Date: Apr. 6, 2023

(30) Foreign Application Priority Data
Oct. 23, 2020 (JP) 2020-178027

(51) Int. Cl. G03F 7/09; G03F 7/115; G03F 7/039; G03F 7/038; G03F 7/028

(52) U.S. Cl. CPC G03F 7/094; G03F 7/115; G03F 7/039; G03F 7/038; G03F 7/028

(57) ABSTRACT

The present disclosure provides a photosensitive resin multilayer body which comprises a support film and a photosensitive resin layer that is superposed on the support film. The photosensitive resin layer contains from 30% by mass to 70% by mass of an alkali-soluble polymer, from 20% by mass to 50% by mass of a compound that has an ethylenically unsaturated double bond, and from 0.01% by mass to 20% by mass of a photopolymerization initiator. The alkali-soluble polymer has an acid equivalent weight of 350 or more, while containing, as a copolymerization component, a (meth)acrylate that has an aromatic group. The compound that has an ethylenically unsaturated double bond contains from 50% by mass to 100% by mass of an acrylate monomer based on the total mass of the compound, while having a double-bond equivalent weight of 150 or more. The photosensitive resin layer has a thickness of 30 μm or more.

### FIELD

The present disclosure relates to a photosensitive resin layered product.

### BACKGROUND

Manufacturing of printed-wiring boards, precision processing of metals, and the like have been conventionally carried out by photolithography methods. Photosensitive resin layered products for use in photolithography methods are classified into negative type products with removal of unexposed regions by dissolution and positive type products with removal of exposed regions by dissolution.

A general method for forming a pattern with a photosensitive resin layered product is here simply described. First, a protection layer is stripped from a photosensitive resin layered product. A laminator is used to stack a photosensitive resin layer and a support on a substrate such as a copper clad layered plate or a copper sputtered thin film so that the substrate, the photosensitive resin layer, and the support are located in the listed order. The photosensitive resin layer is exposed with a photomask having a desired wiring pattern being interposed. The support is stripped from the layered product after exposure, thereafter an unexposed region or an exposed region is removed by dissolution or dispersion with a developer, and thus a resist pattern is formed on the substrate. A board having a resist pattern is subjected to plating treatment such as copper plating or solder plating, and thus a bump for semiconductors or the like can be formed.

Various photosensitive resin layered products have been studied for resist pattern or semiconductor bump formation. For example, Patent Literatures 1 to 7 have each described photosensitive resin layered products having a photosensitive resin layer containing specified alkali-soluble polymer, photo-polymerizable monomer and photo-polymerizable initiator.

### CITATION LIST

### Patent Literature

[PTL 1] WO 2009/078380
[PTL 2] Japanese Unexamined Patent Publication No. 2011-227309
[PTL 3] WO 2011/037182
[PTL 4] Japanese Unexamined Patent Publication No. 2013-246387
[PTL 5] Japanese Unexamined Patent Publication No. 2014-002285
[PTL 6] Japanese Unexamined Patent Publication No. 2014-126701
[PTL 7] WO 20191088268

### SUMMARY

### Technical Problem

In recent years, miniaturization of wiring and high densification have been demanded, and accordingly plating techniques have been expanded as methods for metal wiring formation. The shapes of wirings formed by plating techniques depend on the shapes and thicknesses of resist patterns. In plating techniques, in general, photosensitive resin layered products having thick photosensitive resin layers are used, and obtaining high resolution and reduction of a phenomenon where photosensitive resin layers are not removed and partially remain in tapered shapes (so-called “trailing”) are demanded.

If photosensitive resins inferior in processability with strippers are used, cured resists stripped are not dissolved and then remain as residues in strippers. Such remaining stripping residues cause pump clogging in stripping machines. Thus, there is a demand for processability of photosensitive resins with strippers (hereinafter, also referred to as “stripping processability”). Strippers for use in removal of cured resist patterns consume components contained therein, along with the removal. If photosensitive resins remarkably consuming components are used, failures such as stripping residues easily occur and deterioration in productivity is caused unless the frequency of making up of stripper baths is increased. Thus, a reduction in frequency of making up of stripper baths (hereinafter, also referred to as “resistance to stripper fatigue”) is demanded.

Photosensitive resins for use in plating techniques are also demanded to be reduced in phenomenon where plates are subducted into bottoms of cured resist patterns during plating treatment (hereinafter, also referred to as “under-plating”).

Accordingly, an object of the present disclosure is to provide a photosensitive resin layered product which can allow for an enhancement in resolution, a reduction in trailing, enhancements in stripper processability and resistance to stripper fatigue, and suppression of under-plating.

### Solution to Problem

Aspects of the present disclosure are listed in the following Items.

[1]

A photosensitive resin layered product comprising a support film and a photosensitive resin layer stacked on the support film, wherein
the photosensitive resin layer comprises
   (A) 30 wt % to 70 wt % of an alkali-soluble polymer,
   (B) 20 wt % to 50 wt % of an ethylenically unsaturated double bond-containing compound, and
   (C) 0.01 wt % to 20 wt % of a photopolymerization initiator.
the alkali-soluble polymer comprises an aromatic group-containing (meth)acrylate as a copolymerization component and has an acid equivalent of 350 or more,
the ethylenically unsaturated double bond-containing compound comprises 50 wt % to 100 wt % of an acrylate monomer based on the total weight of the ethylenically unsaturated double bond-containing compound, and has a double bond equivalent of 150 or more, and the photosensitive resin layer has a thickness of 30 μm or more.
   [2]

The photosensitive resin layered product according to Item 1, wherein the alkali-soluble polymer comprises benzyl (meth)acrylate as a copolymerization component.

[3]

The photosensitive resin layered product according to Item 1 or 2, wherein, when the thickness of the photosensitive resin layer is designated as T [μm] and the absorbance at a wavelength of 365 nm of the photosensitive resin layer is designated as A, a relationship represented by the following expression: 0<A/T≤0.007; is satisfied.

[4]

The photosensitive resin layered product according to any one of Items 1 to 3, wherein the alkali-soluble polymer comprises 45 wt % to 95 wt % of benzyl (meth)acrylate as a copolymerization component.

[5]

The photosensitive resin layered product according to any one of Items 1 to 4, wherein the alkali-soluble polymer comprises 50 wt % or more of benzyl (meth)acrylate as a copolymerization component.

[6]

The photosensitive resin layered product according to any one of Items 1 to 4, wherein the alkali-soluble polymer comprises 70 wt % or more of benzyl (meth)acrylate as a copolymerization component.

[7]

The photosensitive resin layered product according to any one of Items 1 to 6, wherein the ethylenically unsaturated double bond-containing compound comprises an acrylate monomer and a methacrylate monomer.

[8]

The photosensitive resin layered product according to Item 7, wherein the weight ratio between the acrylate monomer and the methacrylate monomer (acrylate monomer/methacrylate monomer) is 1.2 or more and 25.0 or less.

[9]

The photosensitive resin layered product according to any one of Items 1 to 8, wherein the alkali-soluble polymer is free of styrene and a styrene derivative as copolymerization components.

[10]

The photosensitive resin layered product according to any one of Items 1 to 9, wherein the alkali-soluble polymer has an acid equivalent of 370 or more.

[11]

The photosensitive resin layered product according to any one of Items 1 to 9, wherein the alkali-soluble polymer has an acid equivalent of 410 or more.

[12]

The photosensitive resin layered product according to any one of Items 1 to 11, wherein the ethylenically unsaturated double bond-containing compound is free of a trimethylolpropane backbone-containing compound.

[13]

The photosensitive resin layered product according to any one of Items 1 to 12, wherein the ethylenically unsaturated double bond-containing compound comprises a tetra- or higher functional compound.

[14]

The photosensitive resin layered product according to any one of Items 1 to 13, wherein the ethylenically unsaturated double bond-containing compound comprises 50 wt % to 99 wt % of an acrylate monomer based on the total weight of the ethylenically unsaturated double bond-containing compound.

[15]

The photosensitive resin layered product according to any one of Items 1 to 13, wherein the ethylenically unsaturated double bond-containing compound comprises 60 wt % to 99 wt % of an acrylate monomer based on the total weight of the ethylenically unsaturated double bond-containing compound.

[16]

The photosensitive resin layered product according to any one of Items 1 to 13, wherein the ethylenically unsaturated double bond-containing compound comprises 70 wt % to 99 wt % of an acrylate monomer based on the total weight of the ethylenically unsaturated double bond-containing compound.

[17]

The photosensitive resin layered product according to any one of Items 1 to 16, wherein the ethylenically unsaturated double bond-containing compound has a double bond equivalent of 200 or more.

[18]

The photosensitive resin layered product according to any one of Items 1 to 17, wherein the weight ratio between the alkali-soluble polymer and the ethylenically unsaturated double bond-containing compound (A/B) is 1.40 or more.

[19]

The photosensitive resin layered product according to any one of Items 1 to 17, wherein the weight ratio between the alkali-soluble polymer and the ethylenically unsaturated double bond-containing compound (A/B) is 1.60 or more.

[20]

The photosensitive resin layered product according to any one of Items 1 to 17, wherein the weight ratio between the alkali-soluble polymer and the ethylenically unsaturated double bond-containing compound (A/B) is 1.80 or more.

[21]

The photosensitive resin layered product according to any one of Items 1 to 20, wherein the photopolymerization initiator comprises a 2,4,5-triarylimidazole dimer.

[22]

The photosensitive resin layered product according to any one of Items 1 to 21, wherein the thickness of the photosensitive resin layer is more than 40 sm.

[23]

The photosensitive resin layered product according to any one of Items 1 to 21, wherein the thickness of the photosensitive resin layer is more than 70 μm.

[24]

The photosensitive resin layered product according to any one of Items 1 to 21, wherein the thickness of the photosensitive resin layer is more than 100 μm.

[25]

The photosensitive resin layered product according to any one of Items 1 to 21, wherein the thickness of the photosensitive resin layer is more than 150 μm.

[26]

The photosensitive resin layered product according to any one of Items 1 to 21, wherein the thickness of the photosensitive resin layer is more than 200 μm.

### Advantageous Effects of Invention

According to the present disclosure, a photosensitive resin layered product is provided which can allow for an enhancement in resolution, a reduction of resist foot, enhancements in stripper processability and resistance to stripper fatigue, and suppression of under-plating.

### BRIEF DESCRIPTION OF DRAWINGS

FIG. 1 illustrates SEM photographs respectively representing examples of cases of small resist foot (a) and small under-plating (b).

FIG. 2 illustrates SEM photographs respectively representing examples of cases of large resist foot (a) and large under-plating (b).

FIG. 3 illustrates an SEM photograph representing failures in formation and stripping of a copper pillar with a photosensitive resin poor in resistance to stripper fatigue.

### DESCRIPTION OF EMBODIMENTS

<<Photosensitive Resin Layered Product>>

A photosensitive resin layered product of the present disclosure comprises a support film, and a photosensitive resin layer stacked on the support film. The photosensitive resin layered product is preferably a dry film resist. The photosensitive resin layer may have, if necessary, a protection layer on a surface thereof, the surface being opposite to the support film.

The photosensitive resin layer comprises (A) 30 wt % to 70 wt % of an alkali-soluble polymer, (B) 20 wt % to 50 wt % of an ethylenically unsaturated double bond-containing compound, and (C) 0.01 wt % to 20 wt % of a photopolymerization initiator. The photosensitive resin layer may optionally contain, in addition to the components (A) to (C), a polymer other than the component (A), a monomer other than the component (B) and an initiator other than the component (C), as well as additional component(s), for example, a dye, an antioxidant, and/or a plasticizer.

<(A) Alkali-Soluble Polymer>

The alkali-soluble polymer comprises an aromatic group-containing (meth)acrylate as a copolymerization component. The amount of the alkali-soluble polymer is 30 wt % to 70 wt %, preferably 40 wt % to 70 wt %, more preferably 50 wt % to 70 wt % based on the total solid weight of the photosensitive resin layer. An aromatic group-containing (meth)acrylate is contained as a copolymerization component, and therefore an advantage is that, for example, shortening in minimum development time, an enhancement in resolution, a reduction in trailing, and an enhancement in under-plating resistance are obtained. Herein, the alkali-soluble polymer is a polymer soluble in an aqueous alkaline solution. The (meth)acrylate means acrylate or methacrylate, and (meth)acrylic means acrylic or methacrylic.

The aromatic group in the aromatic group-containing (meth)acrylate is preferably an aromatic group having 6 to 20 carbon atoms, and examples thereof include a phenyl group, a benzyl group, a biphenyl group, and a naphthyl group. A hydrogen atom in the aromatic group may be unsubstituted or substituted, and when substituted, examples of a substituent include a hydrocarbon group having 1 to 5 carbon atoms, a hydroxyl group, and a halogen group. The aromatic group-containing (meth)acrylate preferably comprises benzyl (meth)acrylate from the viewpoints of shortening in minimum development time, an enhancement in resolution, a reduction in trailing, and a more enhancement in under-plating resistance. The ratio of benzyl (meth)acrylate contained as a copolymerization component in the alkali-soluble polymer is preferably 45 wt % or more, more preferably 50 wt % or more, further preferably 60 wt % or more, still further preferably 70 wt % or more based on the weight of the entire monomer constituting the alkali-soluble polymer. When the ratio of benzyl (meth)acrylate is higher, more favorable stripper processability is achieved. The amount of benzyl (meth)acrylate is preferably less than 100 wt %, more preferably 95 wt % or less, further preferably 90 wt % or less based on the amount of the entire monomer constituting the alkali-soluble polymer.

The alkali-soluble polymer has an acid equivalent of 350 or more, preferably 370 or more, more preferably 380 or more, further preferably 390 or more, still further preferably 400 or more, particularly preferably 410 or more. The acid equivalent refers to a weight (unit: gram) of the alkali-soluble polymer per equivalent of a carboxyl group. When the acid equivalent is 350 or more, an advantage is that, for example, shortening in minimum development time, an enhancement in resolution, resistance to stripper fatigue, and prevention of resist wrinkles during storage are achieved. The upper limit of the acid equivalent is not limited, and is preferably, for example, 600 or less. When the acid equivalent is 600 or less, developability and strippability can be enhanced.

The weight average molecular weight of the alkali-soluble polymer is preferably 5,000 or more and 500,000 or less, more preferably 5,000 or more and 300,000 or less, further preferably 10,000 or more and 200,000 or less, still further preferably 20,000 or more and 100,000 or less.

When the weight average molecular weight is 5,000 or more, a decrease of a development aggregate, as well as properties of an unexposed film, such as edge fusibility and cut/chip performance of the photosensitive resin layered product, are improved. On the other hand, when the weight average molecular weight is 500,000 or less, solubility in a developer is enhanced. Herein, the “edge fusibility” refers to the property of suppression of a phenomenon where, when the photosensitive resin layered product is wound up in a roll shape, the photosensitive resin layer is spread out from an end of the roll. The “cut/chip performance” refers to the property of suppression of a phenomenon where, when an unexposed film is cut by a cutter, chips are flown. If such cut/chip performance is inferior, for example, chips flown can be attached to an upper surface or the like of the photosensitive resin layered product and the chips can be transferred to a mask in a subsequent exposure step to thereby cause any failure.

The alkali-soluble polymer may contain a copolymerization component other than the aromatic group-containing (meth)acrylate. Examples of such a copolymerization component include carboxylic acid, carboxylate and acid anhydride each having at least one polymerizable unsaturated group in its molecule, for example, (meth)acrylic acid, fumaric acid, cinnamic acid, crotonic acid, itaconic acid, maleic anhydride, maleic acid semi-ester, (meth)acrylic acid, and alkyl (meth)acrylate; (meth)acrylonitrile and (meth)acrylamide; and aromatic vinyl compounds such as styrene and a styrene derivative. Examples of the styrene derivative include oxystyrene, hydroxystyrene, acetoxystyrene, alkylstyrene, and halogenoalkylstyrene.

The alkyl group of the alkyl (meth)acrylate may be linear, branched, or cyclic, and the number of carbon atoms therein may be, for example, 1 or more, 2 or more, 3 or more, 4 or more, 5 or more or 6 or more, 12 or less, 11 or less, 10 or less, 9 or less, or 8 or less. More specific examples of the alkyl group of the alkyl (meth)acrylate include a methyl group, an ethyl group, a n-propyl group, an isopropyl group, a n-butyl group, an isobutyl group, a tert-butyl group, a pentyl group, a hexyl group, a heptyl group, an octyl group, an ethylhexyl group, a nonyl group, a decyl group, an undecyl group, and a dodecyl group. In particular, a 2-ethylhexyl group is still further preferable from the viewpoints of shortening in development time and a reduction in trailing of a resist pattern. For example, 2-ethylhexyl (meth)acrylate can be used for some of monomers for use in synthesis of the alkali-soluble polymer, and thus the alkali-soluble polymer, which comprises 2-ethylhexyl acrylate as a copolymerization component, can be obtained.

Examples of a preferable combination of copolymerization components in the alkali-soluble polymer include (meth)acrylic acid and benzyl (meth)acrylate; (meth)acrylic acid, benzyl (meth)acrylate and an aromatic vinyl compound; and (meth)acrylic acid, benzyl (meth)acrylate and alkyl (meth)acrylate. More specific examples thereof include methacrylic acid and benzyl methacrylate; acrylic acid, benzyl methacrylate and styrene; and acrylic acid, benzyl methacrylate and 2-ethylhexyl acrylate.

<(B) Ethylenically Unsaturated Double Bond-Containing Compound>

The photosensitive resin layer comprises 20 wt % to 50 wt %, preferably 20 wt % to 40 wt % of an ethylenically unsaturated double bond-containing compound based on the total solid weight of the photosensitive resin layer. The ethylenically unsaturated double bond can be irradiated with light in the presence of a photopolymerization initiator to thereby allow the photosensitive resin layer to be cured.

The ethylenically unsaturated double bond-containing compound comprises an acrylate monomer. The amount of the acrylate monomer is 50 wt % or more, preferably 60 wt % or more, more preferably 70 wt % or more, further preferably 80 wt % or more, still further preferably 90 wt % or more, or may be 100 wt %, based on the total weight of the ethylenically unsaturated double bond-containing compound. The amount of the acrylate monomer is 100 wt % or less, preferably 99 wt % or less, further preferably 95 wt % or less based on the total weight of the ethylenically unsaturated double bond-containing compound. When the amount of the acrylate monomer is in the above range, stripper processability, resistance to stripper fatigue and under-plating resistance tend to be enhanced. The ethylenically unsaturated double bond-containing compound may contain other monomer, for example, a methacrylate monomer as long as it comprises the acrylate monomer. The ethylenically unsaturated double bond-containing compound preferably comprises the acrylate monomer and the methacrylate monomer because stripper processability, resistance to stripper fatigue, under-plating resistance, and the like tend to be more enhanced. The weight ratio (acrylate monomer/methacrylate monomer) between the acrylate monomer and the methacrylate monomer is preferably 1.2 or more and 25.0 or less, more preferably 1.2 or more and 20.0 or less, further preferably 1.2 or more and 15.0 or less from the same viewpoint.

The double bond equivalent of the ethylenically unsaturated double bond-containing compound is 150 or more, preferably 160 or more, more preferably 170 or more, further preferably 180 or more, still further preferably 190 or more, particularly preferably 200 or more. When the double bond equivalent is 150 or more, under-plating resistance, stripper processability and resistance to stripper fatigue tend to be enhanced. The upper limit value of the double bond equivalent of the ethylenically unsaturated double bond-containing compound is not limited, and may be, for example, 500 or less, 400 or less, or 300 or less. Herein, the “double bond equivalent” means a molecular weight per ethylenically unsaturated double bond.

The number of functional groups in the ethylenically unsaturated double bond-containing compound may be 1, and is preferably 2 or more, more preferably 3 or more, further preferably 4 or more, 5 or more, or 6 or more. Herein, the “number of functional groups” is the number of ethylenically unsaturated double bonds per molecule of the compound, and is defined as, for example, the number of acryloyl groups per molecule in the case of the acrylate monomer. The ethylenically unsaturated double bond-containing compound comprises a compound large in number of functional groups, resulting in a tendency to allow under-plating resistance of a resist pattern to be improved. This effect is remarkably exerted in particular when the acrylate monomer is a tetra- or higher functional acrylate monomer.

Examples of a monofunctional ethylenic double bond-containing compound include a compound with (meth)acrylic acid added to one end of (poly)alkylene glycol; and a compound with (meth)acrylic acid added to one end of (poly)alkylene glycol and no ethylenic double bond present at other end thereof, for example, a compound with an alkyl group added. The alkylene of the (poly)alkylene glycol is an alkylene group preferably having 2 to 10 carbon atoms, more preferably 2 to 4 carbon atoms, and examples thereof include a 1,2-ethylene group, a 1,2-propylene group, and a butylene group.

Examples of a bi- or higher functional compound include a compound having (poly)alkylene glycol, bisphenol A, trimethylolpropane, glycerin, pentaerythritol, dipentaerythritol, or the like as a backbone, and having a structure in which at least two or all of hydrogen atoms of these hydroxyl groups are each substituted with a functional group having an ethylenically unsaturated double bond, preferably a functional group having a (meth)acrylate group, more preferably a functional group having an acrylate group. The ethylenically unsaturated double bond-containing compound more preferably does not comprise a trimethylolpropane backbone-containing compound, from the viewpoint of under-plating resistance.

Examples of a bifunctional ethylenically unsaturated double bond-containing compound having (poly)alkylene glycol as a backbone include a compound represented by the following general formula (I):

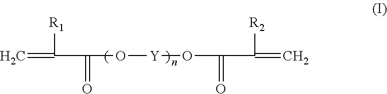

wherein each Y independently represents an alkylene group, R₁ and R₂ each independently represent a methyl group or a hydrogen atom, and each n independently represents an integer of 1 to 50.

In the general formula (I), each Y is independently an alkylene group preferably having 2 to 10 carbon atoms, more preferably 2 to 4 carbon atoms, and examples thereof include a 1,2-ethylene group, a 1,2-propylene group, and a butylene group. A (Y—O) moiety may contain different alkylene oxide repeating units, or may be configured from the same alkylene oxide repeating units. When the (Y—O) moiety comprises different alkylene oxides, the arrangement may be a random, alternating, or block arrangement. n represents an integer of 1 to 50, preferably 3 to 20, more preferably 6 to 10.

More specific examples of the compound represented by the general formula (I) include:

hexaethylene glycol dimethacrylate,
heptaethylene glycol dimethacrylate,
octaethylene glycol dimethacrylate,
nonaethylene glycol dimethacrylate,
decaethylene glycol dimethacrylate,
hexapropylene glycol dimethacrylate,
heptapropylene glycol dimethacrylate,
octapropylene glycol dimethacrylate,
nonapropylene glycol dimethacrylate, and
decapropylene glycol dimethacrylate.

The double bond equivalent of the (meth)acrylate monomer represented by the general formula (I) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

Examples of a bifunctional ethylenically unsaturated double bond-containing compound having bisphenol A as a backbone include a compound represented by the following general formula (II):

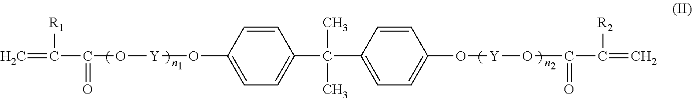

wherein each Y independently represents an alkylene group, R₁ and R₂ each independently represent a methyl group or a hydrogen atom, and n₁ and n₂ each independently represent an integer of 1 to 100.

The backbone has an aromatic ring, resulting in a tendency to allow under-plating resistance to be improved.

In the general formula (II), each Y is independently an alkylene group preferably having 2 to 10 carbon atoms, more preferably 2 to 4 carbon atoms, and examples thereof include a 1,2-ethylene group, a 1,2-propylene group, and a butylene group. At least one Y or all Y(s) is/are preferably each a 1,2-ethylene group from the viewpoints of, for example, impartment of flexibility to a cured film, an enhancement in film strength, suppression of development aggregation, and an increase in reactivity of an ethylenically unsaturated double bond. A (Y—O) moiety may contain different alkylene oxide repeating units, or may be configured from the same alkylene oxide repeating units. When the (Y—O) moiety comprises different alkylene oxides, the arrangement may be a random, alternating, or block arrangement. n₁ and n₂ each independently represent an integer of 1 to 100, preferably 1 to 50, more preferably 1 to 20, further preferably 1 to 10, and preferably 2≤n₁+n₂≤200, more preferably 2≤n₁+n₂≤100, further preferably 2≤n₁+n₂≤40, particularly preferably 2≤n₁+n₂≤20 is satisfied.

More specific examples of the compound represented by the general formula (II) include:

ethylene glycol diacrylate with 1 mol on average of ethylene oxide added to each of both ends of bisphenol A,
ethylene glycol diacrylate with 2 mol on average of ethylene oxide added to each of both ends of bisphenol A,
ethylene glycol diacrylate with 5 mol on average of ethylene oxide added to each of both ends of bisphenol A,
alkylene glycol diacrylate with 6 mol on average of ethylene oxide and 2 mol on average of propylene oxide added to each of both ends of bisphenol A,
alkylene glycol diacrylate with 15 mol on average of ethylene oxide and 2 mol on average of propylene oxide added to each of both ends of bisphenol A,
ethylene glycol dimethacrylate with 1 mol on average of ethylene oxide added to each of both ends of bisphenol A,
ethylene glycol dimethacrylate with 2 mol on average of ethylene oxide added to each of both ends of bisphenol A,
ethylene glycol dimethacrylate with 5 mol on average of ethylene oxide added to each of both ends of bisphenol A,
alkylene glycol dimethacrylate with 6 mol on average of ethylene oxide and 2 mol on average of propylene oxide added to each of both ends of bisphenol, and
alkylene glycol dimethacrylate with 15 mol on average of ethylene oxide and 2 mol on average of propylene oxide added to each of both ends of bisphenol A.

The double bond equivalent of the (meth)acrylate monomer represented by the general formula (II) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

Examples of a trifunctional ethylenically unsaturated double bond-containing compound having trimethylolpropane as a backbone include a compound represented by the following general formula (III):

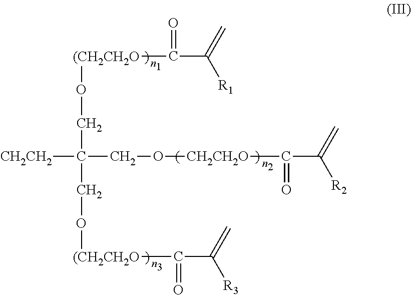

wherein n₁, n₂ and n₃ are each independently an integer of 1 to 25, provided that n₁+n₂+n₃ is an integer of 3 to 75, and R₁, R₂ and R₃ are each independently a methyl group or a hydrogen atom.

In the general formula (III), n₁, n₂ and n₃ are each independently an integer of 1 to 25, preferably 1 to 10, more preferably 1 to 3. n₁+n₂+n₃ is an integer of 3 to 75, preferably 3 to 30, more preferably 3 to 15, further preferably 3 to 9. n₁+n₂+n₃ is preferably 9 or more from the viewpoints of suppression of the occurrence of resist trailing, an enhancement in film strength, and impartment of flexibility to a cured film. n₁+n₂+n₃ is preferably 75 or less from the viewpoints of high resolution and close contact ability, and favorable stripping characteristics, and from the viewpoint of suppression of edge fusibility.

Specific examples of the compound represented by the general formula (III) include:

triacrylate with a total of 3 mol on average of ethylene oxide added to hydroxyl group ends of trimethylolpropane,
triacrylate with a total of 9 mol on average of ethylene oxide added to hydroxyl group ends of trimethylolpropane,
triacrylate with a total of 15 mol on average of ethylene oxide added to hydroxyl group ends of trimethylolpropane, and
triacrylate with a total of 30 mol on average of ethylene oxide added to hydroxyl group ends of trimethylolpropane.

The double bond equivalent of the (meth)acrylate monomer represented by the general formula (III) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

Examples of a trifunctional ethylenically unsaturated double bond-containing compound having glycerin as a backbone include a compound represented by the following formula (VI):

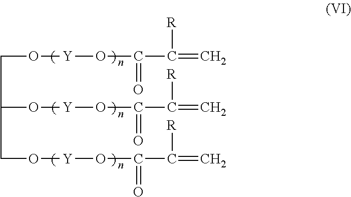

wherein each Y independently represents an alkylene group, each R independently represents a methyl group or a hydrogen atom, and each n independently represents an integer of 0 to 200.

In the general formula (VI), each Y is independently an alkylene group preferably having 2 to 10 carbon atoms, more preferably 2 to 4 carbon atoms, and examples thereof include a 1,2-ethylene group, a 1,2-propylene group, and a butylene group. At least one Y or all Y(s) is/are preferably each a 1,2-ethylene group from the viewpoints of, for example, impartment of flexibility to a cured film, an enhancement in film strength, suppression of development aggregation, and an increase in reactivity of an ethylenically unsaturated double bond. A (Y—O) moiety may contain different alkylene oxide repeating units, or may be configured from the same alkylene oxide repeating units. When the (Y—O) moiety comprises different alkylene oxides, the arrangement may be a random, alternating, or block arrangement. Each n independently represents an integer of 0 to 200, and at least one n is preferably an integer of 1 to 200 and three n(s) are each more preferably an integer of 1 to 200. In the general formula (VI), n may be 0, namely, no alkylene oxide moiety may be present. The total n is preferably 1 or more from the viewpoints of suppression of the occurrence of resist trailing, an enhancement in film strength, and impartment of flexibility to a cured film. The total n is preferably 200 or less from the viewpoints of high resolution and close contact ability, and favorable stripping characteristics, and from the viewpoint of suppression of edge fusibility.

The double bond equivalent of the (meth)acrylate monomer represented by the general formula (IV) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

Examples of a tetrafunctional ethylenically unsaturated double bond-containing compound having pentaerythritol as a backbone include a compound represented by the following general formula (V):

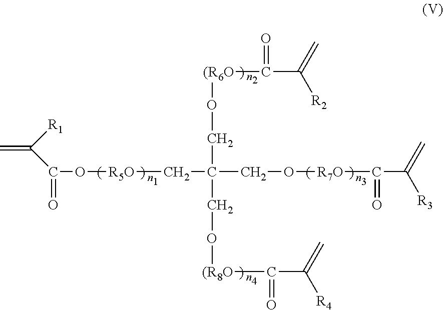

wherein n₁, n₂, n₃ and n₄ each independently represent an integer of 1 to 25, n₁+n₂+n₃+n₄ is an integer of 4 to 100, R₁, R₂, R₃ and R₄ each independently represent a methyl group or a hydrogen atom, R₅, R₆, R₇, and R₈ each independently represent an alkylene group, and when R₅, R₆, R₇ and R₈ are each plurally present, R₅(s), R₆(s), R₇(s) and R₈(s) may be each the same as or different from each other.

In the general formula (V), R₅, R₆, R₇ and R₈ each independently represent an alkylene group preferably having 2 to 10 carbon atoms, more preferably 2 to 4 carbon atoms, and examples thereof include a 1,2-ethylene group, a 1,2-propylene group, and a butylene group. At least one or all of R₅, R₆, R₇ and R₈ is/are preferably each a 1,2-ethylene group from the viewpoints of, for example, impartment of flexibility to a cured film, an enhancement in film strength, suppression of development aggregation, and an increase in reactivity of an ethylenically unsaturated double bond. n₁+n₂+n₃+n₄ is 4 to 100, preferably 4 to 80, more preferably 4 to 40, still further preferably 4 to 20, particularly preferably 4 to 16. n₁+n₂+n₃+n₄ is preferably 4 or more from the viewpoints of suppression of the occurrence of resist trailing, an enhancement in film strength, and impartment of flexibility to a cured film. n₁+n₂+n₃+n₄ is preferably 100 or less from the viewpoints of high resolution and close contact ability, and favorable stripping characteristics, and from the viewpoint of suppression of edge fusibility.

Specific examples of the compound represented by the general formula (V) include:

tetraacrylate with a total of 4 mol on average of ethylene oxide added to hydroxyl group ends of pentaerythritol,
tetraacrylate with a total of 9 mol on average of ethylene oxide added to hydroxyl group ends of pentaerythritol,
tetraacrylate with a total of 12 mol on average of ethylene oxide added to hydroxyl group ends of pentaerythritol,
tetraacrylate with a total of 15 mol on average of ethylene oxide added to hydroxyl group ends of pentaerythritol,
tetraacrylate with a total of 20 mol on average of ethylene oxide added to hydroxyl group ends of pentaerythritol,
tetraacrylate with a total of 28 mol on average of ethylene oxide added to hydroxyl group ends of pentaerythritol, and
tetraacrylate with a total of 35 mol on average of ethylene oxide added to hydroxyl group ends of pentaerythritol.

The double bond equivalent of the (meth)acrylate monomer represented by the general formula (V) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

Examples of a hexafunctional ethylenically unsaturated double bond-containing compound having dipentaerythritol as a backbone include a compound represented by the following general formula (VI):

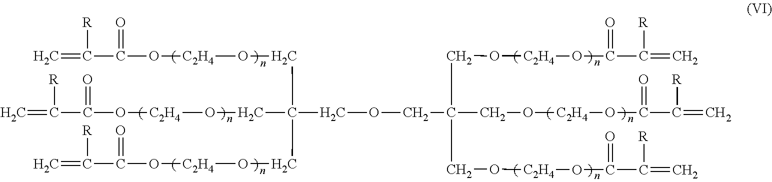

wherein each R independently represents a methyl group or a hydrogen atom, and each n is independently an integer of 0 to 30.

In the general formula (VI), n may be 0, namely, no alkylene oxide moiety may be present.

In the general formula (VI), each n is independently an integer of 0 to 30, preferably 1 to 20, more preferably 2 to 10, further preferably 3 to 5. The total n is 0 to 180, preferably 6 to 120, more preferably 12 to 60, further preferably 18 to 30. The total n is preferably 1 or more from the viewpoints of suppression of the occurrence of resist trailing, an enhancement in film strength, and impartment of flexibility to a cured film. The total n is preferably 180 or less from the viewpoints of high resolution and close contact ability, and favorable stripping characteristics, and from the viewpoint of suppression of edge fusibility.

Specific examples of the hexaacrylate compound represented by the general formula (VI) include:

dipentaerythritol hexaacrylate,
hexaacrylate with a total of 1 to 36 mol of ethylene oxide added to six ends of dipentaerythritol,
hexaacrylate with a total of 6 to 30 mol of ethylene oxide added to six ends of dipentaerythritol,
hexaacrylate with a total of 12 to 30 mol of ethylene oxide added to six ends of dipentaerythritol,
hexaacrylate with a total of 18 to 30 mol of ethylene oxide added to six ends of dipentaerythritol, and
hexaacrylate with a total of 1 to 10 mol of ε-caprolactone added to six ends of dipentaerythritol.

The double bond equivalent of the (meth)acrylate monomer represented by the general formula (VI) is preferably 150 or more, more preferably 160 or more, further preferably 170 or more, still further preferably 180 or more, and is arbitrarily 500 or less, 400 or less, or 300 or less, from the viewpoints of under-plating resistance, stripper processability and resistance to stripper fatigue.

The acrylate monomer contained in the ethylenically unsaturated double bond-containing compound is preferably at least one acrylate compound having a double bond equivalent of 150 or more, among, preferably, the compound represented by the general formula (III), the compound represented by the general formula (V), and the compound represented by the general formula (VI).

Herein, it is more preferable not to contain an acrylate compound having trimethylolpropane as a backbone, represented by the general formula (III), from the viewpoint of a more enhancement in under-plating resistance.

The weight ratio (A/B) between the alkali-soluble polymer and the ethylenically unsaturated double bond-containing compound is preferably 1.40 or more, more preferably 1.60 or more, further preferably 1.80 or more. When the weight ratio of A/B is in the above range, stripper processability and resistance to stripper fatigue tend to be enhanced and resist wrinkles during storage tend to be suppressed.

<(C) Photopolymerization Initiator>

The photopolymerization initiator is a compound which can be irradiated with light in the presence of the ethylenically unsaturated double bond-containing compound to thereby allow polymerization of the ethylenically unsaturated double bond-containing compound to be initiated.

The amount of the photopolymerization initiator in the photosensitive resin layer is 0.01 wt % to 20 wt %, preferably 0.3 wt % to 10 wt %, more preferably 1 wt % to 5 wt % based on the total solid weight of the photosensitive resin layer. When the amount of the photopolymerization initiator is 0.01 wt % or more, an exposure pattern having a sufficient residual film rate after development can be obtained. When the amount of the photopolymerization initiator is 20 wt % or less, light is allowed to sufficiently penetrate to the bottom of a resist, high resolution is obtained, and development aggregation in a developer can be suppressed.

Examples of the photopolymerization initiator include an imidazole compound, an aromatic ketone compound, an acridine-based compound, and an N-aryl-α-amino acid compound. The photopolymerization initiator may be used singly or in combination of two or more kinds thereof.

The imidazole compound tends to impart under-plating resistance and suppress trailing of a resist pattern. Examples of the imidazole compound include aliphatic group-containing imidazole compounds such as methylimidazole, 2-ethyl-4-methylimidazole, 1-isobutyl-2-methylimidazole, 2-ethyl-4-methylimidazole, ethylimidazole, isopropylimidazole, 2,4-dimethylimidazole, undecylimidazole, and heptadecylimidazole; and aromatic group-containing imidazole compounds such as 1-benzyl-2-methylimidazole, phenylimidazole (for example, 2-phenylimidazole), 2-phenyl-4-methylimidazole, 2-phenyl-4,5-dihydroxymethylimidazole, 2-phenyl-4-methyl-5-hydroxymethylimidazole, triarylimidazole, and a dimer thereof. In particular, aromatic group-containing imidazole compounds are preferable, triarylimidazole (for example, rofin) or a dimer thereof is more preferable, and a triarylimidazole dimer is further preferable from the viewpoints of plating resistance and suppression of the occurrence of trailing.

Examples of the triarylimidazole dimer include 2,4,5-triarylimidazole dimers such as a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

The aromatic ketone compound is preferable from the viewpoint of an enhancement in sensitivity. Examples of the aromatic ketone compound include benzophenone, N,N′-tetramethyl-4,4′-dimethylaminobenzophenone (Michler's ketone), N,N′-tetraethyl-4,4′-diaminobenzophenone, 4-methoxy-4′-dimethylaminobenzophenone, 4,4′-bis(diethylamino)benzophenone, 2-benzyl-2-dimethylamino-1-(4-morpholinophenyl)-butanone-1, and 2-methyl-1-[4-(methylthio)phenyl]-2-morpholino-propanone-1. In particular, 4,4′-bis(diethylamino)benzophenone is preferable.

The acridine-based compound is preferable from the viewpoints of an enhancement in sensitivity, and achievement of both high sensitivity and suppression of trailing. Examples of the acridine-based compound include 1,7-bis(9,9′-acridinyl)heptane, 9-phenylacridine, 9-methylacridine, 9-ethylacridine, 9-chloroethylacridine, 9-methoxyacridine, 9-ethoxyacridine, 9-(4-methylphenyl)acridine, 9-(4-ethylphenyl)acridine, 9-(4-n-propylphenyl)acridine, 9-(4-n-butylphenyl)acridine, 9-(4-tert-butylphenyl)acridine, 9-(4-methoxyphenyl)acridine, 9-(4-ethoxyphenyl)acridine, 9-(4-acetylphenyl)acridine, 9-(4-dimethylaminophenyl)acridine, 9-(4-chlorophenyl)acridine, 9-(4-bromophenyl)acridine, 9-(3-methylphenyl)acridine, 9-(3-tert-butylphenyl)acridine, 9-(3-acetylphenyl)acridine, 9-(3-dimethylaminophenyl)acridine, 9-(3-diethylaminophenyl)acridine, 9-(3-chlorophenyl)acridine, 9-(3-bromophenyl)acridine, 9-(2-pyridyl)acridine, 9-(3-pyridyl)acridine, and 9-(4-pyridyl)acridine. In particular, 1,7-bis(9,9′-acridinyl)heptane or 9-phenylacridine is preferable in terms of sensitivity, resolution, availability, and the like.

The N-aryl-α-amino acid compound is preferable from the viewpoint of an enhancement in sensitivity. Examples of the N-aryl-α-amino acid compound include N-phenylglycine, N-methyl-N-phenylglycine, and N-ethyl-N-phenylglycine.

Further examples of the photopolymerization initiator include

quinone compounds such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone, and 2,3-dimethylanthraquinone;
benzoin ether compounds such as benzoin methyl ether, benzoin ethyl ether, and benzoin phenyl ether;
benzyl derivatives such as benzyl methyl ketal;
coumarin-based compounds; and
pyrazoline derivatives such as 1-phenyl-3-(4-tert-butyl-styryl)-5-(4-tert-butyl-phenyl)-pyrazoline, 1-phenyl-3-(4-biphenyl)-5-(4-tert-butyl-phenyl)-pyrazoline, and 1-phenyl-3-(4-biphenyl)-5-(4-tert-octyl-phenyl)-pyrazoline.

<Dye>

The photosensitive resin layer may further contain a dye. The dye may contain at least one selected from a Leuco dye, a fluorane dye, and other coloring substance. The photosensitive resin layer comprises such a component, and thus an exposed section emits color and therefore viewability is enhanced. Furthermore, in a case where an alignment marker for exposure is read by an inspection machine or the like, the contrast between an exposed region and an unexposed region is increased and recognition is easier.

Examples of the Leuco dye include tris(4-dimethylaminophenyl)methane [Leuco Crystal Violet] and bis(4-dimethylaminophenyl)phenylmethane [Leuco Malachite Green]. The Leuco dye is preferably Leuco Crystal Violet from the viewpoint of an improvement in contrast.

Examples of the fluorane dye include 2-(dibenzylamino)fluorane, 2-anilino-3-methyl-6-diethylaminofluorane, 2-anilino-3-methyl-6-dibutylaminofluorane, 2-anilino-3-methyl-6-N-ethyl-N-isoamylaminofluorane, 2-anilino-3-methyl-6-N-methyl-N-cyclohexylaminofluorane, 2-anilino-3-chloro-6-diethylaminofluorane, 2-anilino-3-methyl-6-N-ethyl-N-isobutylaminofluorane, 2-anilino-6-dibutylaminofluorane, 2-anilino-3-methyl-6-N-ethyl-N-tetrahydrofurfurylaminofluorane, 2-anilino-3-methyl-6-piperidinoaminofluorane, 2-(o-chloroanilino)-6-diethylaminofluorane, and 2-(3,4-dichloroanilino)-6-diethylaminofluorane.

The amount of the Leuco dye or the fluorane dye in the photosensitive resin layer is preferably 0.1 wt % to 10 wt %, more preferably 0.2 wt % to 5 wt %, further preferably 0.3 wt % to 1 wt % based on the total solid weight of the photosensitive resin layer. When the amount of the dye is 0.1 wt % or more, the contrast between an exposed section and an unexposed section tends to be enhanced. When the amount of the dye is 10 wt % or less, the photosensitive resin layer tends to be enhanced in storage stability and the occurrence of an aggregate during development tends to be suppressed.

Examples of the coloring substance include fuchsin, phthalocyanine green, an auramine base, paramagenta, crystal violet, methyl orange, Nile Blue 2B, Malachite Green (Aizen (registered trademark) MALACHITE GREEN manufactured by Hodogaya Chemical Co., Ltd.), Basic Blue 7 (for example, Aizen (registered trademark) Victoria Pure Blue BOH cone). Basic Blue 20, Diamond Green (Aizen (registered trademark) DIAMOND GREEN GH manufactured by Hodogaya Chemical Co., Ltd.).

The amount of the coloring substance in the photosensitive resin layer is preferably 0.001 wt % to 1 wt % based on the total solid weight of the photosensitive resin layer. When the amount of the coloring substance is 0.001 wt % or more, the contrast tends to be enhanced, and when the amount is 1 wt % or less, storage stability tends to be enhanced.

<Halogen Compound>

The photosensitive resin layer may further contain a halogen compound and preferably comprises a halogen compound in combination with the Leuco dye. When a combination of the Leuco dye and the halogen compound is contained, close contact ability and the contrast tend to be enhanced.

Examples of the halogen compound include amyl bromide, isoamyl bromide, isobutylene bromide, ethylene bromide, diphenylmethyl bromide, benzyl bromide, methylene bromide, tribromomethylphenylsulfone, carbon tetrabromide, tris(2,3-dibromopropyl)phosphate, trichloroacetamide, amyl iodide, isobutyl iodide, 1,1,1-trichloro-2,2-bis(p-chlorophenyl)ethane, and a chlorinated triazine compound. In particular, the halogen compound is preferably tribromomethylphenylsulfone. A halogen compound such as tribromomethylphenylsulfone, when used in combination with the acridine-based compound as the photopolymerization initiator, exerts a large effect, and is preferable from the viewpoints of, for example, an enhancement in resolution, an enhancement in close contact ability, an enhancement in sensitivity, an enhancement in contrast, an enhancement in tent film piercing resistance, suppression of resist trailing, and an enhancement in etching resistance.

The content of the halogen compound in the photosensitive resin layer is preferably 0.01 wt % based on the total solid weight of the photosensitive resin layer from the above viewpoints. The content is more preferably 0.1 wt % or more, further preferably 0.3 wt % or more, particularly preferably 0.5 wt % or more. The content is preferably 3 wt % or less from the viewpoint of sustention of storage stability as a color phase in a photosensitive layer, and from the viewpoint of suppression of the occurrence of an aggregate during development. The content is more preferably 2 wt % or less, further preferably 1.5 wt % or less.

<Antioxidant>

The photosensitive resin layer may further contain an antioxidant. The antioxidant can allow for enhancements in heat stability and storage stability of the photosensitive resin layer. The antioxidant is preferably at least one compound selected from the group consisting of a radical polymerization initiator, a benzotriazole compound and a carboxybenzotriazole compound.

Examples of the radical polymerization initiator include p-methoxyphenol, hydroquinone, pyrogallol, naphthylamine, tert-butylcatechol, biphenol, cuprous chloride, 2,6-di-tert-butyl-p-cresol, 2,2′-methylenebis(4-methyl-6-tert-butylphenol), 2,2′-methylenebis(4-ethyl-6-tert-butylphenol), 4,4′-thiobis(6-tert-butyl-m-cresol), 4,4′-butylidenebis(3-methyl-6-tert-butylphenol), 1,1,3-tris(2-methyl-4-hydroxy-5-tert-butylphenyl)butane, styrenated phenol (for example, trade name “Antage SP” manufactured by KAWAGUCHI CHEMICAL INDUSTRY CO., LTD.), tribenzyl phenol (for example, trade name “TBP”, phenol compound having 1 to 3 benzyl groups, manufactured by KAWAGUCHI CHEMICAL INDUSTRY CO., LTD.), and diphenylnitrosoamine.

Examples of the benzotriazole compound include 1,2,3-benzotriazole, 1-chloro-1,2,3-benzotriazole, bis(N-2-ethylhexyl)aminomethylene-1,2,3-benzotriazole, bis(N-2-ethylhexyl)aminomethylene-1,2,3-tolyltriazole, and bis(N-2-hydroxyethyl)aminomethylene-1,2,3-benzotriazole.

Examples of the carboxybenzotriazole compound include 4-carboxy-1,2,3-benzotriazole, 5-carboxy-1,2,3-benzotriazole, N—(N,N-di-2-ethylhexyl)aminomethylene carboxybenzotriazole, N—(N,N-di-2-hydroxyethyl)aminomethylene carboxybenzotriazole, N—(N,N-di-2-ethylhexyl)aminoethylene carboxybenzotriazole, and a mixture thereof. In particular, a mixture of 4-carboxy-1,2,3-benzotriazole and 5-carboxy-1,2,3-benzotriazole is preferable, and the mixing ratio as the weight ratio is about 1:1.

The total content of the antioxidant is preferably 0.01 wt % to 3 wt %, more preferably 0.05 wt % to 1 wt % based on the total solid weight of the photosensitive resin layer. When the amount of the antioxidant is 0.01 wt % or more, the photosensitive resin layer tends to be enhanced in storage stability, and when the amount is 3 wt % or less, sensitivity tends to be retained and decoloration of the dye tends to be suppressed.

<Plasticizer>

The photosensitive resin layer may contain, if necessary, a plasticizer. Examples of the plasticizer include glycol esters such as polyethylene glycol, polypropylene glycol, polyoxypropylene polyoxyethyleneether, polyoxyethylene monomethyl ether, polyoxypropylene monomethyl ether, polyoxyethylene polyoxypropylene monomethyl ether, polyoxyethylene monoethyl ether, polyoxypropylene monoethyl ether, and polyoxyethylene polyoxypropylene monoethyl ether;

phthalate compounds such as diethyl phthalate;
o-toluenesulfonic acid amide, p-toluenesulfonic acid amide, tributyl citrate, triethyl citrate, triethyl acetyl citrate, tri-n-propyl acetyl citrate, tri-n-butyl acetyl citrate, and the like; propylene glycol with propylene oxide added to both ends of bisphenol A, ethylene glycol with ethylene oxide added to both ends of bisphenol A, and the like; and
an aluminum salt with 1 to 3 mol of nitrosophenylhydroxylamine added, and the like. Such a plasticizer may be used singly or in combination of two or more kinds thereof. In particular, an aluminum salt with 1 to 3 mol of nitrosophenylhydroxylamine added is preferable from the viewpoint of under-plating resistance.

The amount of the plasticizer in the photosensitive resin layer is preferably 1 wt % to 50 wt %, more preferably 1 wt % to 30 wt % based on the total solid weight of the photosensitive resin layer. When the amount of the plasticizer is 1 wt % or more, the development time tends to be inhibited from being delayed and flexibility tends to be imparted to a cured film, and when the amount is 50 wt % or less, curing failures and edge phase tend to be suppressed.

<Solvent>

The photosensitive resin layer can be formed by coating a support film with a solution where each component is dissolved in a solvent, and then drying the resultant, as described below. The resulting photosensitive resin layer may include the remaining solvent. Examples of the solvent include ketone compounds typified by methyl ethyl ketone (MEK), and alcohol compounds typified by methanol, ethanol and isopropanol.

<Thickness>

The thickness of the photosensitive resin layer is 30 μm or more, preferably more than 40 μm, more preferably more than 70 μm, further preferably more than 100 μm, still further preferably more than 150 μm, particularly preferably more than 200 μm. In a plating technique, the photosensitive resin layered product, which has a thick photosensitive resin layer (30 μm or more), is used. The photosensitive resin layer can be thick to thereby inhibit air during lamination from occurring and provide a more suitable photosensitive resin layered product for plating techniques. The upper limit of the thickness of the photosensitive resin layer is not limited, and can be, for example, 500 μm or less, 400 μm or less, or 300 μm or less.

<Absorbance>

The photosensitive resin layered product preferably satisfies a relationship represented by the following expression: 0<A/T≤0.007; where the thickness of the photosensitive resin layer is designated as T (μm) and the absorbance at a wavelength of 365 nm of the photosensitive resin layer is designated as A. While a thicker layer, in particular, a thickness T of more than 100 μm causes light to hardly reach the bottom of the photosensitive resin layer and makes crosslinking difficult, it is meant that the photosensitive resin layered product, which satisfies the relationship, allows light to easily reach the bottom even if thick. Accordingly, the photosensitive resin layered product is preferable from the viewpoints of an enhancement in resolution, a reduction in trailing, and enhancements in stripper processability and resistance to stripper fatigue, as compared with a photosensitive resin layered product satisfying a relationship represented by A/T>0.007.

<Support Film>

The support film is desirably transparent so as to allow light emitted from an exposure source to penetrate. Examples of the support film include a polyethylene terephthalate film, a polyvinyl alcohol film, a polyvinyl chloride film, a vinyl chloride copolymer film, a polyvinylidene chloride film, a vinylidene chloride-copolymerized film, a polymethyl methacrylate copolymer film, a polystyrene film, a polyacrylonitrile film, a styrene copolymer film, a polyamide film, and a cellulose derivative film. Such a film can also be, if necessary, stretched. The haze of the support film is preferably 5 or less. The thickness of the support film, while is advantageously thinner in terms of image formability and economic efficiency, is preferably 10 μm to 30 μm also in consideration of a function for strength retention.

<Protection Layer>

The photosensitive resin layered product may have a protection layer on a surface of the photosensitive resin layer, the surface being opposite to the support film. The protection layer serves to protect the photosensitive resin layer. The protection layer preferably has an appropriate close contact force with the photosensitive resin layer. In other words, preferably, the close contact force of the protection layer with the photosensitive resin layer is sufficiently smaller than the close contact force of the support film with the photosensitive resin layer and the protection layer can be easily stripped from the photosensitive resin layered product. For example, a polyethylene film, a polypropylene film, or a film excellent in strippability, recited in Japanese Unexamined Patent Publication No. S59-202457, can be used as the protection layer. The thickness of the protection layer is preferably 10 μm to 100 μm, more preferably 10 to 50 μm.

<<Method for Producing Photosensitive Resin Layered Product>>

The photosensitive resin layered product can be produced by sequentially stacking the photosensitive resin layer, and, if necessary, the protection layer on the support film. The stacking method here adopted can be a known method. For example, each component for use in the photosensitive resin layer is mixed with a solvent for dissolution thereof and thus a uniform solution (coating liquid) is obtained. Examples of the solvent include ketone compounds typified by methyl ethyl ketone (MEK), and alcohol compounds typified by methanol, ethanol and isopropanol. The amount of the solvent is preferably an amount so that the viscosity of the coating liquid at 25° C. is 500 to 4,000 mPa·s. The support film can be coated with the coating liquid, and dried, to thereby form the photosensitive resin layer on the support film. A known method can be adopted for the coating, and examples thereof include a method using a bar coater or a roll coater.

Next, the protection layer can be, if necessary, laminated on the photosensitive resin layer, to thereby produce the photosensitive resin layered product.

<<Method for Forming Resist Pattern and Semiconductor Bump>>

A resist pattern can be formed by use of the photosensitive resin layered product of the present disclosure. A resist pattern formation method can comprise:
a step of laminating the photosensitive resin layer of the photosensitive resin layered product on a substrate (lamination step),
a step of exposing the photosensitive resin layered product laminated (exposure step),
a step of developing the photosensitive resin layered product exposed, to thereby form a resist pattern (development step), and
optionally, a step of heating the resist pattern obtained (heating step).

A semiconductor bump can be formed with the substrate where the resist pattern is formed. A semiconductor bump formation method can comprise:
optionally, a descumming and pre-plating treatment step,
a step of copper plating or solder plating the substrate where the resist pattern is formed, to thereby form a semiconductor bump (plating step),
optionally, a step of etching the substrate where the resist pattern is formed (etching step), and
optionally, a step of stripping a resist pattern from the substrate (stripping step).

Hereinafter, a series of methods for forming a resist pattern and a semiconductor bump are exemplified with the photosensitive resin layered product and a sputtered copper thin film as the substrate.

(1) Lamination Step

For example, the photosensitive resin layered product, while the protection layer thereof is stripped, is allowed to closely contact with the substrate, for example, a sputtered copper thin film by use of, for example, a hot roll laminator. The sputtered copper thin film is preferably a copper-sputtered silicon wafer where a copper layer is formed on a silicon wafer by a sputtering apparatus.

(2) Exposure Step

The exposure step can be, for example:
a step of exposing the photosensitive resin layer of the photosensitive resin layered product, stacked on the substrate, in a state where the photosensitive resin layer is closely contact with a mask film having a desired wiring pattern, with the mask film being interposed,
a step of exposing the desired wiring pattern by a direct imaging exposure method, or
a step of exposing an image of a photomask by an exposure method involving projection with a lens being interposed.

(3) Development Step

After the exposure step, the support film on the photosensitive resin layer can be stripped and an unexposed region (in the case of a negative type) or an exposed region (in the case of a positive type) can be removed by development with a developer of an aqueous alkaline solution, to thereby form a resist pattern on the substrate. An aqueous Na₂CO₃ or K₂CO₃ solution can be used as the aqueous alkaline solution. The aqueous alkaline solution can be appropriately selected depending on properties of the photosensitive resin layer, and an aqueous Na₂CO₃ solution at about 20 to 40° C. having a concentration of about 0.2 to 2 wt % is preferably used.

(4) Heating Step

Optionally, a step of heating the resist pattern formed, at, for example, about 100° C. to 300° C. for 1 minute to 5 hours may be further performed. The heating step is performed to thereby enable a cured resist pattern obtained to be further enhanced in close contact ability and chemical resistance. The heating here can be conducted by a heating furnace of, for example, a hot air, infrared ray or far-infrared ray system.

(5) Descumming and Pre-Plating Treatment

Optionally, descumming and pre-plating treatment can be performed by subjecting the substrate where the resist pattern is formed, to plasma treatment and/or water immersion treatment.

(6) Plating Step

A substrate surface exposed by development (for example, a copper surface of the sputtered copper thin film) can be copper plated or solder plated, to thereby produce a conductor pattern. A plating liquid is preferably a copper sulfate plating liquid.

(7) Etching Step

Optionally, an etching liquid may be sprayed from above onto the resist pattern formed through the steps, to thereby etch a copper surface not covered with the resist pattern and thus form a circuit pattern. The etching method here performed can be, for example, acidic etching or alkaline etching, and is performed by a method suitable for the photosensitive resin layered product to be used.

(8) Stripping Step

Thereafter, the layered product can be treated with an aqueous solution having stronger alkalinity than the developer, to thereby strip the resist pattern from the substrate. The stripper is preferably at least one selected from the group consisting of an aqueous NaOH or KOH solution at about 40 to 70° C. having a concentration of about 2 to 5 wt %; SPR920 (product name); and R-101 (product name). Herein, a small amount of an aqueous solvent may be added to the stripper.

The photosensitive resin layered product, the resist pattern and the semiconductor bump described above can be utilized for, for example, formation of a semiconductor package.

### EXAMPLES

<<Measurement and Evaluation Methods>>

<Acid Equivalent>

The acid equivalent was determined with a titrator (for example, Hiranuma automatic titrator (COM-555) manufactured by Hiranuma Co., Ltd.) according to a potentiometric titration method with an aqueous 0.1 mol/L sodium hydroxide solution.

<Absorbance>

The absorbance (A) at a wavelength of 365 nm of the photosensitive resin layered product was measured with an ultraviolet-visible (UV-Vis) measurement apparatus (Model U-3010 spectrophotometer manufactured by Hitachi High-Technologies Corporation). A protection film was stripped from the photosensitive resin layered product, and the absorbance at 365 nm was measured and the resulting value was defined as the absorbance (A). Air was used as a blank sample.

<Air During Lamination>

A wafer substrate after lamination was observed, and the number of bubbles having a diameter of 1 μm or more, generated between a photosensitive resin and the wafer, was counted and ranked as follows.
E (Excellent): a number of bubbles of 0
G (Good): a number of bubbles of 1 or more and 5 or less
F (Fair): a number of bubbles of 6 or more and 10 or less
P (Poor): a number of bubbles of 11 or more

<Minimum Development Time>

The minimum time taken for complete dissolution of a photosensitive resin layer in an unexposed section was measured as the “minimum development time”, and ranked as follows.
E (Excellent): a minimum development time value of 300 seconds or less
G (Good): a minimum development time value of more than 300 seconds and 320 seconds or less
F (Fair): a minimum development time value of more than 320 seconds and 340 seconds or less
P (Poor): a minimum development time value of more than 340 seconds

<Resolution>

The minimum value of a hole mask, where a cured resist pattern was normally formed, was defined as the resolution and ranked as follows.
E (Excellent): a resolution of 100 μm or less
G (Good): a resolution of more than 100 μm and 120 μm or less
F (Fair): a resolution of more than 120 μm and 130 μm or less
P (Poor): a resolution of more than 130 μm

<Resist Trailing>

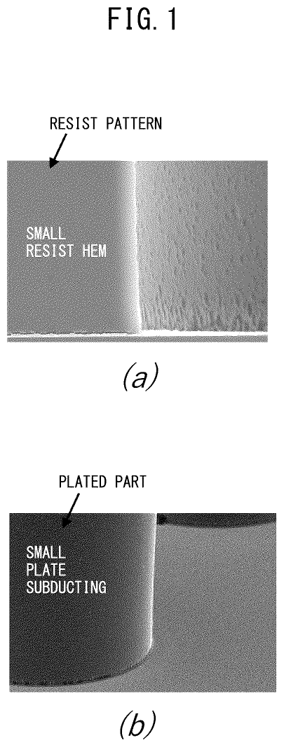

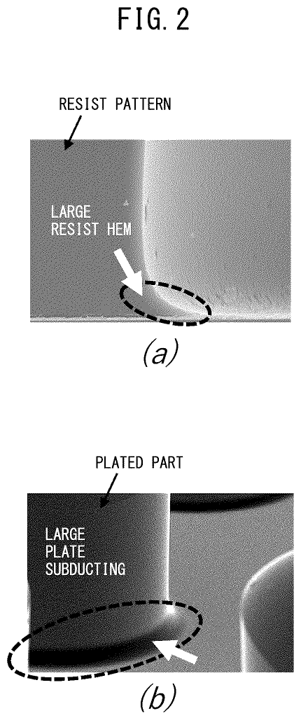

Holes of 150 μm were patterned, a board subjected to descumming treatment was cut out, and the foot length of a resist bottom was observed with SEM. The results were ranked as follows. An example of small resist trailing is illustrated in FIG. 1(a) and an example of large resist trailing is illustrated in FIG. 2(a).
E (Excellent): a foot length of 3 μm or less;
G (Good): a foot length of more than 3 μm and 4 μm or less;
F (Fair): a foot length of more than 4 μm and 5 μm or less;
P (Poor): a foot length of more than 5 μm

<Under-Plating Resistance>

After copper plating, copper post bottoms of holes of 150 μm in a board where a cured resist was stripped were observed with SEM, and ranked as follows. An example of small under-plating is illustrated in FIG. 1(b) and an example of large under-plating is illustrated in FIG. 2(b).
E (Excellent): no copper under-plating
G (Good): copper under-plating having a width of 1 μm or less
F (Fair): copper under-plating having a width of more than 1 μm and 3 μm
P (Poor): copper under-plating having a width of more than 3 μm

<Stripper Processability>

Exposure:

The photosensitive resin layered product was exposed from the support film side, and a cured resist was produced. An Ultratech Prisma ghi stepper (manufactured by Ultratech Co., Ltd.) was used for the exposure. The amount of the exposure was 390 mJ/cm².

Development:

A polyethylene film was stripped from the photosensitive resin layered product exposed, and an aqueous 1 wt % Na₂CO₃ solution at 30° C. was sprayed over a period twice the “minimum development time”, for development. Thereafter, a polyethylene terephthalate film was stripped, to thereby obtain a cured resist.

Stripping Processability Evaluation 1:

The cured resist obtained (1.4 cm³) was immersed in 30 mL of a stripper of 3% NaOH at 65° C., for 75 minutes. Thereafter, the remaining cured film was subjected to filtration and dried in vacuum, the residual film rate was determined by dividing the weight of the resulting filtered product by the weight of the cured resist first immersed, and thus stripping processability was evaluated. The results were ranked as follows.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

Stripping Processability Evaluation 2:

The same evaluation as the stripping processability evaluation 1 was made with SPR920 as the stripper.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

Stripping Processability Evaluation 3:

The same evaluation as the stripping processability evaluation 1 was made with R-101 as the stripper.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

<Resistance to Stripper Fatigue>

Resistance to Stripper Fatigue Evaluation 1:

The cured resist (1.4 cm³) obtained by exposure and development under conditions described in the above section “stripper processability” was immersed in 30 mL of a stripper of 3% NaOH at 65° C., for 75 minutes, and thereafter the remaining cured film was subjected to filtration to thereby obtain a filtrate (fatigue stripper). Thereafter, the cured resist (0.007 cm³) obtained by exposure and development under the above conditions was immersed in 30 mL of the fatigue stripper for 75 minutes, thereafter the remaining cured film was subjected to filtration and dried in vacuum, the residual film rate was determined by dividing the weight of the resulting filtered product by the weight of the cured resist immersed, and thus stripping processability was evaluated. The results were ranked as follows.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

Resistance to Stripper Fatigue Evaluation 2:

The same evaluation as the stripping processability evaluation 1 was made with a fatigue stripper produced from SPR920.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

Resistance to Stripper Fatigue Evaluation 3:

The same evaluation as the stripping processability evaluation 1 was made with a fatigue stripper produced from R-101.
E (Excellent): a residual film rate value of 0%
G (Good): a residual film rate value of more than 0% and 10% or less
F (Fair): a residual film rate value of more than 10% and 25% or less
P (Poor): a residual film rate value of more than 25%

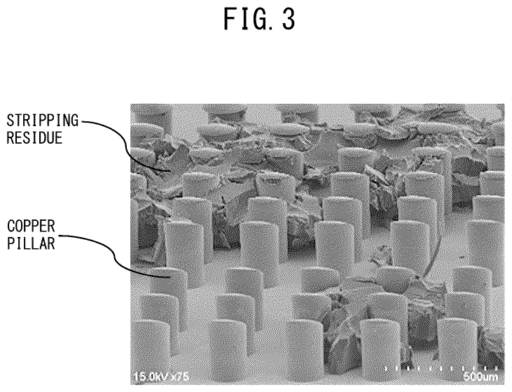

FIG. 3 is an SEM photograph of stripping of the cured resist by a copper pillar formed with a photosensitive resin poor in resistance to stripper fatigue. A stripping residue remains between such copper pillars.

<Resist Wrinkles During Storage>

A photosensitive resin layered product of 8 cm×20 cm was wound on a poly bottle having a diameter of 8.5 cm, and left to still stand under conditions of 23° C. and 50% RH for a certain period, and the degree of wrinkle generation on a resist surface was evaluated, and ranked as follows.
E (Excellent): no wrinkle generation after a lapse of 12 hours or more
G (Good): wrinkle generation after more than 6 hours and within 12 hours
F (Fair): wrinkle generation after more than 3 hours and within 6 hours
P (Poor): wrinkle generation within 3 hours

### Example 1

<Production of Photosensitive Resin Layered Product>

A coating liquid of a photosensitive resin was obtained by stirring and mixing materials shown in Table 1 below at compositions shown in Table 2 (herein, the number with respect to each component represented the amount of compounding (parts by weight) of a solid). A surface of a polyethylene terephthalate film (FB-40 manufactured by Toray Industries, Inc.) having a thickness of 16 μm, as a support film, was uniformly coated with the resulting coating liquid by use of a bar coater, and the resultant was dried in a drier at 95° C. for 12 minutes, to thereby form a photosensitive resin layer. The thickness (T) of the photosensitive resin layer dried was 60 μm.

A photosensitive resin layered product was obtained by attaching a polyethylene film (GF-18 manufactured by TAMAPOLY CO., LTD.) having a thickness of 19 μm, as a protection layer, onto a surface of the photosensitive resin layer, on which no support film was stacked. The absorbance (A) at a wavelength of 365 nm of the photosensitive resin layered product was 0.4067.

The evaluation results are shown in Table 4 below.

<Production of Semiconductor Bump>

Substrate:

In the case of production of a copper post, a substrate used was a copper-sputtered silicon wafer where a copper layer having a thickness of 2000 angstroms (Å) was formed on a 6-inch silicon wafer by a sputtering apparatus (L440S-FHL) manufactured by CANON ANELVA CORPORATION.

Lamination:

The photosensitive resin layered product, while the polyethylene film thereof was stripped, was laminated on the silicon wafer pre-heated to 70° C., at a roll temperature of 70° C. by a hot roll laminator (VA-400III manufactured by Taisei Laminator Co., LTD.). The air pressure was 0.20 MPa and the lamination rate was 0.18 m/min.

Exposure:

Exposure was performed at 390 mJ/cm² by an Ultratech Prisma ghi stepper (manufactured by Ultratech Co., Ltd.) with a glass chromium mask having a hole pattern by 10 μm from 100 μm to 150 μm. The lighting intensity measured on a substrate surface was 2400 mW/cm².

Development:

The polyethylene terephthalate film was stripped from the layered product exposed, and subjected to development by spraying of an aqueous 1 wt %/o Na₂CO₃ solution at 30′C at a flow rate of 200 mL/min., by a spin developer (spin developer AD-1200 manufactured by TAKIZAWA SANGYO K.K.).

Descumming and Pre-Plating Treatment:

Pre-plating treatment was performed by plasma treatment of the substrate with a low-pressure plasma apparatus (EXAM manufactured by SHINKO SEIKI CO., LTD.) under conditions of 50 Pa, 133 W, 02 at 40 mL/min., CF₄ at 1 mL/min., and 1500 seconds.

Copper Sulfate Plating:

A copper post was produced by copper plating as follows and stripping of the substrate as described below. A copper sulfate plating liquid was produced by adding 20 mL of SC-50 R1 (manufactured by MicroFab) and 12 mL of SC-50 R2 (manufactured by MicroFab) to 968 mL of SC-50 MU MA ((registered trademark) manufactured by MicroFab). The substrate (6 cm×12.5 cm) after the pre-plating treatment was plated with the copper sulfate plating liquid produced, by a Haring Cell uniform plating apparatus (manufactured by YAMAMOTO-MS Co., Ltd.) for 100 minutes under regulation of the current value so that copper was deposited at a height of 1 μm per minute. The resulting copper-plated film had a thickness of 100 μm.

Stripping:

The substrate subjected to the plating treatment was stripped with a stripper of 3% NaOH, SPR920 (manufactured by KANTO-PPC Inc.) and R-101 (manufactured by Mitsubishi Gas Chemical Company, Inc.) by heating at 65° C. for 70 minutes.

### Examples 2 to 20 and Comparative Examples 1 to 7

Photosensitive resin layered products, resist patterns and semiconductor bumps were formed and evaluated in the same manner as in Example 1 except that materials and compositions were changed as shown in Tables 1 to 3. The evaluation results are shown in Tables 4 and 5.

TABLE 1

| | |
|---|---|
| A-1 | 50% (solid content) MEK solution of copolymer having a composition of methacrylic acid/benzyl |
| | methacrylate (weight ratio 20/80), having an acid |
| | equivalent of 430, and having a weight average molecular weight of 25000 |
| A-2 | 50% (solid content) MEK solution of copolymer having a composition of methacrylic acid/benzyl |
| | methacrylate (weight ratio 20/80), having an acid |
| | equivalent of 430, and having a weight average molecular weight of 70000 |
| A-3 | 50% (solid content) MEK solution of copolymer having a composition of methacrylic acid/benzyl |
| | methacrylate (weight ratio 22/78), having an acid |
| | equivalent of 390, and having a weight average molecular weight of 50000 |
| A-4 | 50% (solid content) MEK solution of copolymer having a composition of methacrylic acid/benzyl |
| | methacrylate (weight ratio 24/76), having an acid |
| | equivalent of 359, and having a weight average molecular weight of 50000 |
| A-5 | 45% MEK solution of copolymer having a composition of methyl methacrylate/methacrylic |
| | acid/n-butyl acrylate (weight ratio 65/20/15), having an |
| | acid equivalent of 430, and having a weight average molecular weight of 50000 |
| A-6 | 50% (solid content) MEK solution of copolymer having a composition of methacrylic acid/benzyl |
| | methacrylate (weight ratio 25/75), having an acid |
| | equivalent of 344, and having a weight average molecular weight of 50000 |
| A-7 | 50% (solid content) MEK solution of copolymer having a composition of methacrylic acid/benzyl |
| | methacrylate/styrene (weight ratio 20/50/30), having |
| | an acid equivalent of 430, and having a weight average molecular weight of 50000 |
| A-8 | 54% (solid content) MEK solution of copolymer having a composition of methacrylic acid/benzyl |
| | methacrylate/2-ethylhexyl acrylate (weight ratio |
| | 20/60/20), having an acid equivalent of 430, and having a weight average molecular weight of 60000 |
| B-1 | Tetraacrylate (double bond equivalent: 132) with a total of 4 mol on average of ethylene oxide added to ends of pentaerythritol |
| B-2 | Tetraacrylate (double bond equivalent: 187) with a total of 9 mol on average of ethylene oxide added to ends of pentaerythritol |
| B-3 | Tetraacrylate (double bond equivalent: 253) with a total of 15 mol on average of ethylene oxide added to ends of pentaerythritol |
| B-4 | Triacrylate (double bond equivalent: 143) with a total of 3 mol on average of ethylene oxide added to ends of trimethylolpropane |
| B-5 | Triacrylate (double bond equivalent: 231) with a total of 9 mol on average of ethylene oxide added to ends of trimethylolpropane |
| B-6 | Diacrylate (double bond equivalent: 388) with 5 mol of ethylene oxide added to each of both ends of bisphenol A |
| B-7 | Hexaacrylate (double bond equivalent: 267) having a total of 24 mol on average of ethylene oxide at ends of dipentaerythritol |
| B-8 | Dimethacrylate (double bond equivalent: 401) with 5 mol of ethylene oxide added to each of both ends of bisphenol A |
| B-9 | Nonaethylene glycol dimethacrylate (double bond equivalent: 275) |
| B-10 | Heptapropylene glycol dimethacrylate (double bond equivalent: 280) |
| C-1 | 2-(O-chlorophenyl)-4,5-diphenylimidazole dimer |
| C-2 | 4,4′-Bis(diethylamino)benzophenone |
| D-1 | Leuco Crystal Violet |
| D-2 | Aizen Victoria Pure Blue BOH conc. |
| E-1 | Mixture (1:1) of 4-carboxylbenzotriazole and 5-carboxylbenzotriazole |
| F-1 | Aluminum salt with 3 mol of nitrosophenylhydroxylamine added |

TABLE 2

| | Example 1 | Example 2 | Example 3 | Example 4 | Example 5 | Example 6 | Example 7 |
|---|---|---|---|---|---|---|---|
| A-1 | 60 | 60 | 60 | 60 | 60 | 60 | 60 |
| A-2 | | | | | | | |
| A-3 | | | | | | | |
| A-4 | | | | | | | |
| A-5 | | | | | | | |
| A-6 | | | | | | | |
| A-7 | | | | | | | |
| A-8 | | | | | | | |
| B-1 | | | | | | | |
| B-2 | | | | | | | |
| B-3 | | | | | | | |
| B-4 | | | | | | | |
| B-5 | | | | | | | |
| B-6 | | | | | | | |
| B-7 | 33 | 33 | 33 | 50 | 43 | 37 | 33 |
| B-8 | | | | | | | |
| B-9 | | | | | | | |
| B-10 | | | | | | | |
| C-1 | 3 | 3 | 3 | 3 | 3 | 3 | 3 |
| C-2 | 0.025 | 0.025 | 0.025 | 0.025 | 0.025 | 0.025 | 0.042 |
| D-1 | 0.5 | 0.5 | 0.5 | 0.5 | 0.5 | 0.5 | 0.5 |
| D-2 | 0.01 | 0.01 | 0.01 | 0.01 | 0.01 | 0.01 | 0.01 |
| E-1 | 0.01 | 0.01 | 0.01 | 0.01 | 0.01 | 0.01 | 0.01 |
| F-1 | 0.02 | 0.02 | 0.02 | 0.02 | 0.02 | 0.02 | 0.02 |
| Total weight | 96.565 | 96.565 | 96.565 | 113.565 | 106.565 | 100.565 | 96.582 |
| (parts) | | | | | | | |

| | Example 8 | Example 9 | Example 10 | Example 11 | Example 12 | Example 13 |
|---|---|---|---|---|---|---|
| A-1 | 60 | 30 | 30 | 30 | 30 | 30 |
| A-2 | | 30 | 30 | 30 | 30 | 30 |
| A-3 | | | | | | |
| A-4 | | | | | | |
| A-5 | | | | | | |
| A-6 | | | | | | |
| A-7 | | | | | | |
| A-8 | | | | | | |
| B-1 | | | | | | |
| B-2 | | | | 30 | | |
| B-3 | | | | | 30 | |
| B-4 | | | | | | |
| B-5 | | | | | | 30 |
| B-6 | | | | | | |
| B-7 | 30 | 30 | 30 | | | |
| B-8 | 3 | | | | | |
| B-9 | | 3 | | | | |
| B-10 | | | 3 | 3 | 3 | 3 |
| C-1 | 3 | 3 | 3 | 3 | 3 | 3 |
| C-2 | 0.025 | 0.025 | 0.025 | 0.025 | 0.025 | 0.025 |
| D-1 | 0.5 | 0.5 | 0.5 | 0.5 | 0.5 | 0.5 |
| D-2 | 0.01 | 0.01 | 0.01 | 0.01 | 0.01 | 0.01 |
| E-1 | 0.01 | 0.01 | 0.01 | 0.01 | 0.01 | 0.01 |
| F-1 | 0.02 | 0.02 | 0.02 | 0.02 | 0.02 | 0.02 |
| Total weight | 96.565 | 96.565 | 96.565 | 96.565 | 96.565 | 96.565 |
| (parts) | | | | | | |

TABLE 3

| | | | | | | | | Comparative |
|---|---|---|---|---|---|---|---|---|
| | Example 14 | Example 15 | Example 16 | Example 17 | Example 18 | Example 19 | Example 20 | Example 1 |
| A-1 | 30 | 60 | 60 | | | | | |
| A-2 | 30 | | | | | | | |
| A-3 | | | | 60 | | | | |
| A-4 | | | | | 60 | | | |
| A-5 | | | | | | | | 60 |
| A-6 | | | | | | | | |
| A-7 | | | | | | 60 | | |
| A-8 | | | | | | | 60 | |
| B-1 | | | | | | | | |
| B-2 | | | | | | | | |
| B-3 | | | | | | | | |
| B-4 | | | | | | | | |
| B-5 | | | | | | | | |
| B-6 | 30 | | | | | | | |
| B-7 | | 18 | 21 | 33 | 33 | 33 | 33 | 33 |
| B-8 | | 15 | 12 | | | | | |
| B-9 | | | | | | | | |
| B-10 | 3 | | | | | | | |
| C-1 | 3 | 3 | 3 | 3 | 3 | 3 | 3 | 3 |
| C-2 | 0.025 | 0.025 | 0.025 | 0.025 | 0.025 | 0.025 | 0.025 | 0.025 |
| D-1 | 5 | 0.5 | 0.5 | 0.5 | 0.5 | 0.5 | 0.5 | 0.5 |
| D-2 | 0.01 | 0.01 | 0.01 | 0.01 | 0.01 | 0.01 | 0.01 | 0.01 |
| E-1 | 0.01 | 0.01 | 0.01 | 0.01 | 0.01 | 0.01 | 0.01 | 0.01 |
| F-1 | 0.02 | 0.02 | 0.02 | 0.02 | 0.02 | 0.02 | 0.02 | 0.02 |
| Total weight | 101.065 | 96.565 | 96.565 | 96.565 | 96.565 | 96.565 | 96.565 | 96.565 |
| (parts) | | | | | | | | |

| | Comparative | Comparative | Comparative | Comparative | Comparative | Comparative |
|---|---|---|---|---|---|---|
| | Example 2 | Example 3 | Example 4 | Example 5 | Example 6 | Example 7 |
| A-1 | | 60 | 60 | 60 | 60 | 60 |
| A-2 | | | | | | |
| A-3 | | | | | | |
| A-4 | | | | | | |
| A-5 | | | | | | |
| A-6 | 60 | | | | | |
| A-7 | | | | | | |
| A-8 | | | | | | |
| B-1 | | 33 | | | | 33 |
| B-2 | | | | | | |
| B-3 | | | | | | |
| B-4 | | | 33 | | | |
| B-5 | | | | | | |
| B-6 | | | | | | |
| B-7 | 33 | | | 15 | 33 | |
| B-8 | | | | 18 | | |
| B-9 | | | | | | |
| B-10 | | | | | | |
| C-1 | 3 | 3 | 3 | 3 | 33 | 33 |
| C-2 | 0.025 | 0.025 | 0.025 | 0.025 | 0.025 | 0.04 |
| D-1 | 0.5 | 0.5 | 0.5 | 0.5 | 0.5 | 0.5 |
| D-2 | 0.01 | 0.01 | 0.01 | 0.01 | 0.01 | 0.01 |
| E-1 | 0.01 | 0.01 | 0.01 | 0.03 | 0.01 | 0.01 |
| F-1 | 0.02 | 0.02 | 0.02 | 0.02 | 0.02 | 0.02 |
| Total weight | 96.565 | 96.565 | 96.565 | 96.565 | 96.565 | 96.58 |
| (parts) | | | | | | |

TABLE 4

| | Example 1 | Example 2 | Example 3 | Example 4 | Example 5 | Example 6 | Example 7 |
|---|---|---|---|---|---|---|---|
| Acid equivalent of | 430 | 430 | 430 | 430 | 430 | 430 | 430 |
| component A | | | | | | | |
| Double bond equivalent | 267 | 267 | 267 | 267 | 267 | 267 | 267 |
| of component B | | | | | | | |
| Rate of acrylate in | 100% | 100% | 100% | 100% | 100% | 100% | 100% |
| component B | | | | | | | |
| Weight ratio of | 1.82 | 1.82 | 1.82 | 1.20 | 1.40 | 1.62 | 1.82 |
| component A/component B | | | | | | | |
| Thickness T [um] | 60 | 120 | 240 | 240 | 240 | 240 | 240 |
| Absorbance A | 0.4067 | 0.7447 | 1.4202 | 1.2147 | 1.2923 | 1.3665 | 1.9201 |
| A/T | 0.0068 | 0.0062 | 0.0059 | 0.0051 | 0.0054 | 0.0057 | 0.0080 |
| Air during lamination | F | G | E | E | E | E | E |
| Minimum development time | E | E | E | E | E | E | E |
| Resolution | E | E | E | E | E | E | G |
| Resist trailing | E | E | E | E | E | E | G |
| Under-plating resistance | E | E | E | E | E | E | E |
| Stripper processability 1 | G | G | G | [symbol] | G | G | G |
| Stripper processability 2 | G | G | G | F | G | G | G |
| Stripper processability 3 | G | G | G | [symbol] | G | G | G |
| Resistance to stripper | F | [symbol] | [symbol] | [symbol] | [symbol] | [symbol] | [symbol] |
| fatigue 1 | | | | | | | |
| Resistance to stripper | [symbol] | [symbol] | [symbol] | F | [symbol] | F | [symbol] |
| fatigue 2 | | | | | | | |
| Resistance to stripper | F | F | [symbol] | [symbol] | [symbol] | [symbol] | F |
| fatigue 3 | | | | | | | |
| Resist wrinkles during | E | E | E | F | F | G | E |
| storage | | | | | | | |

| | Example 8 | Example 9 | Example 10 | Example 11 | Example 12 | Example 13 |
|---|---|---|---|---|---|---|
| Acid equivalent of | 430 | 430 | 430 | 430 | 430 | 430 |
| component A | | | | | | |
| Double bond equivalent | 279 | 268 | 268 | 195 | 255 | 235 |
| of component B | | | | | | |
| Rate of acrylate in | 91% | 91% | 91% | 91% | 91% | 91% |
| component B | | | | | | |
| Weight ratio of | 1.82 | 1.82 | 1.82 | 1.82 | 1.82 | 3.82 |
| component A/component B | | | | | | |
| Thickness T [um] | 240 | 240 | 240 | 240 | 240 | 240 |
| Absorbance A | 1.4202 | 1.4202 | 1.4202 | 1.4202 | 1.4202 | 1.4202 |
| A/T | 0.0059 | 0.0059 | 0.0059 | 0.0059 | 0.0059 | 0.0059 |
| Air during lamination | E | E | E | E | E | E |
| Minimum development time | E | E | E | E | E | E |
| Resolution | E | E | E | E | E | E |
| Resist trailing | E | E | E | E | E | E |
| Under-plating resistance | E | E | E | E | E | [symbol] |
| Stripper processability 1 | E | E | E | G | E | E |
| Stripper processability 2 | E | E | E | G | E | E |
| Stripper processability 3 | E | E | E | G | E | E |
| Resistance to stripper | E | E | E | G | E | E |
| fatigue 1 | | | | | | |
| Resistance to stripper | E | E | E | G | E | E |
| fatigue 2 | | | | | | |
| Resistance to stripper | E | E | E | G | E | E |
| fatigue 3 | | | | | | |
| Resist wrinkles during | E | E | E | E | E | E |
| storage | | | | | | |

[symbol]

indicates data missing or illegible when filed

TABLE 5

| | | | | | | | | Comparative |
|---|---|---|---|---|---|---|---|---|
| | Example 14 | Example 15 | Example 16 | Example 17 | Example 18 | Example 19 | Example 20 | Example 1 |
| Acid equivalent of | 430 | 430 | 430 | 390 | 359 | 430 | 430 | 430 |
| component A | | | | | | | | |
| Double bond equivalent | 378 | 328 | 316 | 267 | 267 | 267 | 267 | 267 |
| of component B | | | | | | | | |
| Rate of acrylate in | 91% | 55% | 64% | 100% | 100% | 100% | 100% | 100% |
| component B | | | | | | | | |
| Weight ratio of | 1.82 | 1.82 | 1.82 | 1.82 | 1.82 | 1.82 | 1.82 | 1.82 |
| component A/component B | | | | | | | | |
| Thickness T [um] | 240 | 240 | 240 | 240 | 240 | 240 | 240 | 240 |
| Absorbance A | 1.4202 | 1.4202 | 1.4202 | 1.4202 | 1.4202 | 1.4202 | 1.4202 | 1.4202 |
| A/T | 0.0059 | 0.0059 | 0.0059 | 0.0059 | 0.0059 | 0.0059 | 0.0059 | 0.0059 |
| Air during lamination | E | E | E | E | E | E | E | E |
| Minimum development time | E | E | E | E | E | [symbol] | G | P |
| Resolution | [symbol] | E | E | E | E | E | E | P |
| Resist trailing | E | E | E | E | E | E | E | P |
| Under-plating resistance | G | E | E | E | E | E | E | P |
| Stripper processability 1 | E | [symbol] | G | [symbol] | [symbol] | G | G | G |
| Stripper processability 2 | E | [symbol] | G | G | [symbol] | G | G | G |
| Stripper processability 3 | E | [symbol] | G | G | [symbol] | G | G | G |
| Resistance to stripper | E | [symbol] | G | [symbol] | [symbol] | [symbol] | F | [symbol] |
| fatigue 1 | | | | | | | | |
| Resistance to stripper | E | [symbol] | G | [symbol] | [symbol] | [symbol] | [symbol] | [symbol] |
| fatigue 2 | | | | | | | | |
| Resistance to stripper | E | [symbol] | G | [symbol] | [symbol] | [symbol] | [symbol] | [symbol] |
| fatigue 3 | | | | | | | | |
| Resist wrinkles during | E | E | E | E | E | E | E | E |
| storage | | | | | | | | |

| | Comparative | Comparative | Comparative | Comparative | Comparative | Comparative |
|---|---|---|---|---|---|---|
| | Example 2 | Example 3 | Example 4 | Example 5 | Example 6 | Example 7 |
| Acid equivalent of | 344 | 430 | 430 | 430 | 430 | 430 |
| component A | | | | | | |
| Double bond equivalent | 267 | 132 | 143 | 340 | 267 | 132 |
| of component B | | | | | | |
| Rate of acrylate in | 100% | 100% | 100% | 45% | 100% | 100% |
| component B | | | | | | |
| Weight ratio of | 1.82 | 1.82 | 1.82 | 3.82 | 1.82 | 1.82 |
| component A/component B | | | | | | |
| Thickness T [um] | 240 | 240 | 240 | 240 | 25 | 240 |
| Absorbance A | 1.4202 | 1.4202 | 1.4202 | 1.4202 | 0.2097 | 1.861 |
| A/T | 0.0059 | 0.0059 | 0.0059 | 0.0059 | 0.0087 | 0.0078 |
| Air during lamination | E | E | E | E | P | E |
| Minimum development time | G | E | E | E | E | E |
| Resolution | G | E | E | E | E | [symbol] |
| Resist trailing | E | E | E | E | E | P |
| Under-plating resistance | E | E | P | G | E | P |
| Stripper processability 1 | P | P | P | P | G | P |
| Stripper processability 2 | P | P | P | P | G | P |
| Stripper processability 3 | P | P | P | P | G | P |
| Resistance to stripper | P | P | P | P | [symbol] | P |
| fatigue 1 | | | | | | |
| Resistance to stripper | P | P | P | P | [symbol] | P |
| fatigue 2 | | | | | | |
| Resistance to stripper | P | P | P | P | [symbol] | P |
| fatigue 3 | | | | | | |
| Resist wrinkles during | P | E | E | E | E | E |
| storage | | | | | | |

[symbol]

indicates data missing or illegible when filed

### INDUSTRIAL APPLICABILITY

The photosensitive resin layered product of the present disclosure can be used for formation of a resist pattern and a semiconductor bump, and the resist pattern and the semiconductor bump can be utilized for, for example, formation of a semiconductor package.

1. A photosensitive resin layered product comprising a support film and a photosensitive resin layer stacked on the support film, wherein
the photosensitive resin layer comprises
(A) 30 wt % to 70 wt % of an alkali-soluble polymer,
(B) 20 wt % to 50 wt % of an ethylenically unsaturated double bond-containing compound, and
(C) 0.01 wt % to 20 wt % of a photopolymerization initiator,
the alkali-soluble polymer comprises an aromatic group-containing (meth)acrylate as a copolymerization component and has an acid equivalent of 350 or more,
the ethylenically unsaturated double bond-containing compound comprises 50 wt % to 100 wt % of an acrylate monomer based on the total weight of the ethylenically unsaturated double bond-containing compound, and has a double bond equivalent of 150 or more, and
the photosensitive resin layer has a thickness of 30 μm or more.

2. The photosensitive resin layered product according to claim 1, wherein the alkali-soluble polymer comprises benzyl (meth)acrylate as a copolymerization component.

3. The photosensitive resin layered product according to claim 1, wherein, when the thickness of the photosensitive resin layer is designated as T [μm] and the absorbance at a wavelength of 365 nm of the photosensitive resin layer is designated as A, a relationship represented by the following expression: 0<A/T≤0.007; is satisfied.

4. The photosensitive resin layered product according to claim 1, wherein the alkali-soluble polymer comprises 45 wt % to 95 wt % of benzyl (meth)acrylate as a copolymerization component.

5. The photosensitive resin layered product according to claim 1, wherein the alkali-soluble polymer comprises 50 wt % or more, or 70 wt % or more of benzyl (meth)acrylate as a copolymerization component.

6. (canceled)

7. The photosensitive resin layered product according to claim 1, wherein the ethylenically unsaturated double bond-containing compound comprises an acrylate monomer and a methacrylate monomer.

8. The photosensitive resin layered product according to claim 7, wherein the weight ratio between the acrylate monomer and the methacrylate monomer (acrylate monomer/methacrylate monomer) is 1.2 or more and 25.0 or less.

9. The photosensitive resin layered product according to claim 1, wherein the alkali-soluble polymer is free of styrene and a styrene derivative as copolymerization components.

10. The photosensitive resin layered product according to claim 1, wherein the alkali-soluble polymer has an acid equivalent of 370 or more, or 410 or more.

11. (canceled)

12. The photosensitive resin layered product according to claim 1, wherein the ethylenically unsaturated double bond-containing compound is free of a trimethylolpropane backbone-containing compound.

13. The photosensitive resin layered product according to claim 1, wherein the ethylenically unsaturated double bond-containing compound comprises a tetra- or higher functional compound.

14. The photosensitive resin layered product according to claim 1, wherein the ethylenically unsaturated double bond-containing compound comprises 50 wt % to 99 wt %, or 60 wt % to 99 wt % of an acrylate monomer based on the total weight of the ethylenically unsaturated double bond-containing compound.

15. (canceled)

16. The photosensitive resin layered product according to claim 1, wherein the ethylenically unsaturated double bond-containing compound comprises 70 wt % to 99 wt % of an acrylate monomer based on the total weight of the ethylenically unsaturated double bond-containing compound.

17. The photosensitive resin layered product according to claim 1, wherein the ethylenically unsaturated double bond-containing compound has a double bond equivalent of 200 or more.

18. The photosensitive resin layered product according to claim 1, wherein the weight ratio between the alkali-soluble polymer and the ethylenically unsaturated double bond-containing compound (A/B) is 1.40 or more, or 1.60 or more.

19. (canceled)

20. The photosensitive resin layered product according to claim 1, wherein the weight ratio between the alkali-soluble polymer and the ethylenically unsaturated double bond-containing compound is (A/B) 1.80 or more.

21. The photosensitive resin layered product according to claim 1, wherein the photopolymerization initiator comprises a 2,4,5-triarylimidazole dimer.

22. The photosensitive resin layered product according to claim 1, wherein the thickness of the photosensitive resin layer is more than 40 μm, more than 70 μm, more than 100 μm, or more than 150 μm.

23-25. (canceled)

26. The photosensitive resin layered product according to claim 1, wherein the thickness of the photosensitive resin layer is more than 200 μm.
